(19) United States
(12) Patent Application Publication
(10) Pub. No.: US 2017/0367183 A1
(43) Pub. Date: Dec. 21, 2017

(54) CIRCUIT BOARD WITH VIA CAPACITOR STRUCTURE AND MANUFACTURING METHOD FOR THE SAME

(71) Applicant: CHUNGHWA PRECISION TEST TECH. CO., LTD., Taoyuan City (TW)

(72) Inventors: Wen Tsung LI, Taoyuan City (TW); Kai Chieh HSIEH, Taoyuan City (TW); I Hsing WENG, Taoyuan City (TW)

(73) Assignee: CHUNGHWA PRECISION TEST TECH. CO., LTD., Taoyuan City (TW)

(21) Appl. No.: 15/404,213

(22) Filed: Jan. 12, 2017

(30) Foreign Application Priority Data
Jun. 21, 2016 (TW) 105119464

(51) Int. Cl. H05K 1/16; H05K 1/11; H05K 3/40; H05K 3/12; H05K 3/14; H05K 3/16; H05K 3/00

(52) U.S. Cl. CPC H05K 1/162; H05K 3/4076; H05K 1/115; H05K 3/4053; H05K 3/0041; H05K 3/0026; H05K 3/0017; H05K 3/0047; H05K 3/146; H05K 3/16; H05K 3/1241

(57) ABSTRACT

A circuit board with via capacitor structure is introduced herein, including a base, a deposition layer, disposed on the base, having at least a via in the deposition layer, at least a thin film capacitor, each thin film capacitor disposed in each via, each thin film capacitor having a body, a second terminal, and a first terminal, the second terminal and the first terminal located on two opposite sides of the body; at least a first electrode, each first electrode electrically connected to the first terminal of each thin film capacitor; and at least a second electrode, each second electrode electrically connected to the second terminal of each thin film capacitor.

### CROSS-REFERENCE TO RELATED APPLICATIONS

Benefit is claimed to Taiwan Patent Application No. 105119464, filed Jun. 21, 2016; the contents of which are incorporated by reference herein in their entirety.

### FIELD OF THE INVENTION

The present invention relates to a circuit board having a via capacitor structure, and particularly to a circuit board having a via capacitor structure and a manufacturing method for the same.

### BACKGROUND OF THE INVENTION

The capacitor applied in a general printing circuit board (PCB) needs to occupy an area and a volume provided with predetermined sizes as shown in FIG. 1, which is a diagram of the capacitor structure in the existing printed circuit board, including a second electrode 10, a first electrode 11, solder paste 13, and a physical capacitor 14. Because of the effect of the volume of the physical capacitor, the arrangement of the components on the surface of the PCB and the space for welding need to be considered, and the length of the transmission route usually needs to be extended, resulting in the returning route of the signal being too long, thus a particular resistance or inductance is generated, effecting the transmission quality indirectly.

Therefore, it is necessary to provide a capacitor structure with decreased area and volume, to shorten the length of the transmission route, thereby improving the transmission quality.

### SUMMARY OF THE INVENTION

The present invention aims to provide a capacitor structure with a smaller area and volume, to shorten a length of transmission route of the signal, and improve the transmission quality.

An embodiment of the present invention discloses a circuit board having a via capacitor structure, including: a base; a deposition layer disposed on the base, having at least one via in the deposition layer; at least one thin film capacitor, each of the at least one thin film capacitors disposed in each of the at least one vias, each of the at least one thin film capacitors having a body, a second terminal and a first terminal, wherein the second terminal and the first terminal are located on two opposite sides of the body; at least one first electrode, each of the at least one first electrodes electrically connected to the first terminal of each of the at least one thin film capacitors; and at least one second electrode, each of the at least one second electrodes electrically connected to the second terminal of each of the at least one thin film capacitors. A signal is sent from the first electrode to the second electrode via the body of the at least one thin film capacitor in order to allow a collinear route of the first electrode, the body, and the second electrode to transmit the signal.

According to the embodiment of the present invention, the circuit board is manufactured from a core substrate process.

According to the embodiment of the present invention, the circuit board is manufactured from a build-up process.

According to the embodiment of the present invention, the second electrode is a power source electrode, and the first electrode is a ground electrode.

According to the embodiment of the present invention, a surface of the first terminal completely and electrically contacts a surface of each of the at least one first electrodes, and a surface of the second terminal completely and electrically contacts a surface of each of the at least one second electrodes.

According to the embodiment of the present invention, the first electrode, the body, and the second electrode form an alignment state along the collinear route.

According to the embodiment of the present invention, a method of forming the at least one via is selected from a group consisting of machine drill, laser, plasma, and lithography processes.

According to the embodiment of the present invention, a method of forming the at least one thin film capacitor is selected from a group consisting of sputtering, evaporation or atom layer deposit, printing and dispensing.

An embodiment of the present invention discloses a manufacturing method of a circuit board having a via capacitor structure, including the following steps: disposing at least one first electrode on a substrate of the circuit board; covering a deposition layer on the first electrode; manufacturing at least one via in the deposition layer; disposing at least one thin film capacitor in at least one via, each of the at least one thin film capacitors disposed in each of the at least one vias, each of the at least one thin film capacitors having a body, a second terminal, and a first terminal, wherein the second terminal and the first terminal are located on two opposite sides of the body, each of the at least one first electrodes is electrically connected to the first terminal of each of the at least one thin film capacitors; and coating at least one second electrode on the at least one thin film capacitors, each of the at least one second electrodes electrically connected to the second terminal of each of the at least one thin film capacitors.

The disposing and welding method of the capacitor structure used in the present invention is different from that of a physical capacitor. The present invention can change the deposit thin film capacitor process of permittivity according to the requirement of the capacitance, and control the process quality more easily, adjust a thickness of the via through adjusting the aperture and selecting the permittivity of the capacitor material, and apply the second and first electrodes connected in parallel in the via, to form thin film capacitors connected in parallel. Through controlling the number of the thin film capacitors/vias to achieve the predetermined capacitance, and the capacitor trace can be directly performed in the circuit layout, without increasing the element volume; besides, because the signal transmission route is shortened, it is helpful to the power source allocation, and the effect of the current fluctuation in the transmission route is decreased, the power integration is thus improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 illustrates a diagram of a sectional view of a capacitor structure in an existing printed circuit board;

FIG. 2 illustrates a diagram of an exploded view of a capacitor structure in a printed circuit board according to an embodiment of the present invention;

FIG. 3 illustrates a diagram of a sectional view of finished product of the capacitor structure in the printed circuit board in FIG. 2;

FIG. 4 illustrates a diagram of a sectional view of a capacitor structure in a printed circuit board according to another embodiment of the present invention; and

FIG. 5 illustrates a diagram of a manufacture flowchart of a capacitor structure in a printed circuit board according to an embodiment of the present invention.

### DETAILED DESCRIPTION OF THE PREFERRED EMBODIMENTS

As used in this specification the term “embodiment” means an instance, an example, or an illustration. In addition, for the articles in this specification and the appended claims, “a” or “an” in general can be interpreted as “one or more” unless specified otherwise or clear from context to determine the singular form.

In the drawings, the same reference numerals denote units with similar structures.

The present invention aims to provide a capacitor structure with a smaller area and volume to shorten a length of transmission route of signal and improve the transmission quality.

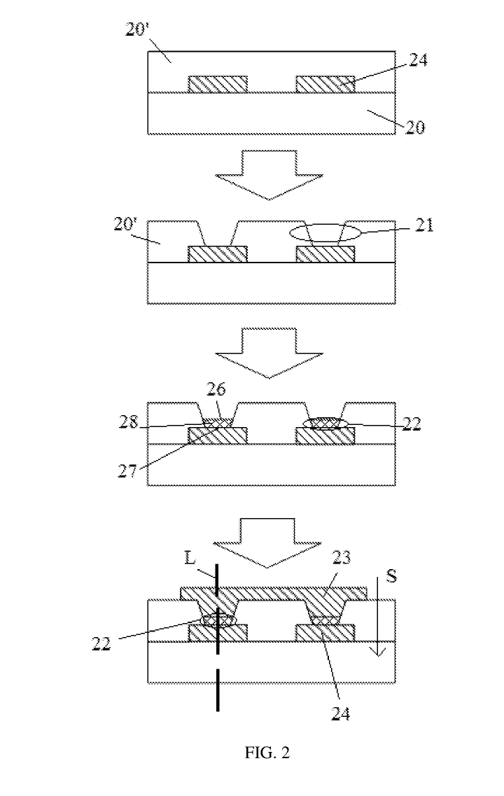

An embodiment of the present invention discloses a circuit board having a via capacitor structure. Please refer to FIG. 2, which illustrates a diagram of an exploded view of a capacitor structure in a printed circuit board according to an embodiment of the present invention, the circuit board having a via capacitor structure, including: a base 20, for example, consisting of an insulation structure; a deposition layer 20′, for example, consisting of an insulation structure, disposed on the base 20, having at least one via 21 in the deposition layer 20′; at least one thin film capacitor 22, each of the at least one thin film capacitors 22 disposed in each of the at least one vias 21, each of the at least one thin film capacitors having a body 28, a second terminal 26 and a first terminal 27, wherein the second terminal 26 and the first terminal 27 are located on two opposite sides of the body 28; at least one first electrode 24, each of the at least one first electrodes 24 electrically connected to a first terminal 27 of each of the at least one thin film capacitors 22, wherein the material of the thin film capacitor 22 could be a material with medium, or high permittivity, and the chemical composition contains a metallic and non-metallic elements, and consists of two or more elements, such as BaTiO₃, TiO₂ etc., if the dielectric material selected has electrical leakage, then an isolation layer such as Ti, TiN, etc., can be added between the electrode and dielectric material; and at least one second electrode 23, each of the at least one second electrodes 23 electrically connected to the second terminal 26 of each of the at least one thin film capacitors 22. A signal S is sent from the first electrode 24 to the second electrode 23 via the body 28 of the thin film capacitor 22 to allow a collinear route L of the first electrode 24, the body 28, and the second electrode 23 (shown as the dotted line in FIG. 2) to transmit the signal S. The second electrode 23 and the first electrode 24 are metal material, and may be alloy, such as Cu, Au, NiCo, etc. The second electrode 23 is a power source electrode and the first electrode 24 is a ground electrode. A surface of the first terminal 27 completely and electrically contacts a surface of each of the at least one first electrodes 24, a surface of the second terminal 26 completely and electrically contacts a surface of each of the at least one second electrodes 23. Besides, the first electrode 24, the body 28, and the second electrode 23 along the collinear route L form an alignment state (shown as the dotted line in FIG. 2).

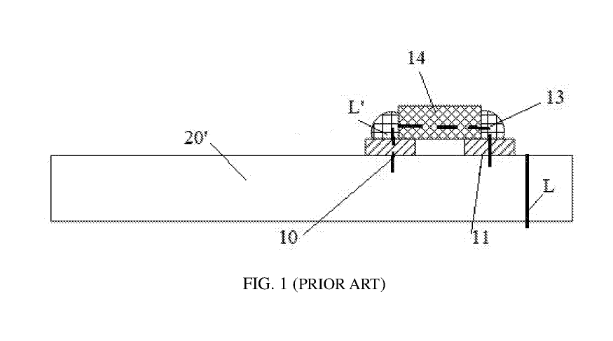

The circuit board structure here is a build-up structure manufactured by a build-up process. The number of the vias in the embodiment is two, this is only for example, not for limiting the present invention. The capacitor structure is generally located on the deposition layer 20′, as the capacitor 14 in FIG. 1, but the via 21 of the present invention is excavated in the deposition layer 20′ in the circuit board, and the second electrode 23 and the first electrode 24 are directly disposed in each via to form the capacitor. Because of the parallel arrangement of the second electrode 23 and the first electrode 24 in each via 21, the at least one thin film capacitor 22 formed in at least one via 21 is capacitor connected in parallel. In this way, because the thin film capacitor 22 is formed in the via 21, under a constant permittivity, a thickness of the via 21, an area of the via 21, and different numbers of the via 21 are adjusted to determine a total capacitance of the capacitor formed, thin film capacitor 22 is directly formed in the via 21, compared to a capacitor generally used on the circuit board, the occupied area is decreased, and the thin film capacitor 22 formed is located in the via 21, directly on the collinear route L along which the signal S is transmitted, compared to a physical capacitor in general, as the capacitor 14 in FIG. 1, the route L′ (shown as the dotted line in FIG. 1) is decreased, the length of transmission route of the signal is further decreased, and closer to the wafer or IC side.

Preferably, a method of forming the at least one via 21 is selected from a group consisting of machine drill, laser, plasma, and lithography processes. For example, drilling by a machine makes the at least one via 21.

Preferably, a method of forming the at least one thin film capacitor 22 is selected from a group consisting of sputtering, evaporation or atom layer deposit, printing and dispensing.

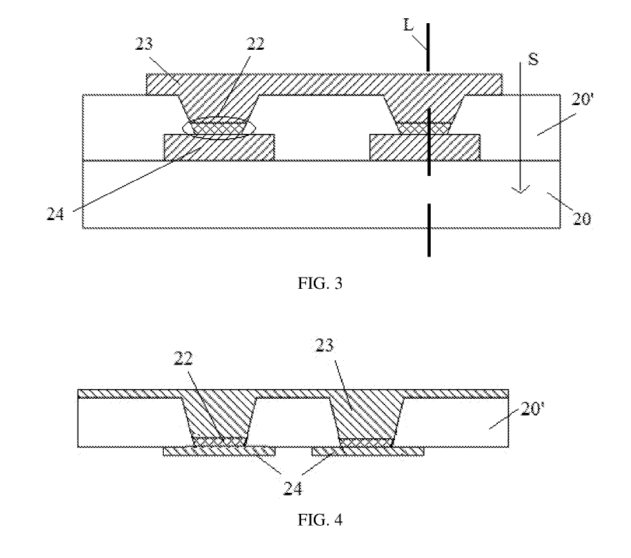

Please refer to FIGS. 3, 4. FIG. 3 illustrates a diagram of a sectional view of finished product of the capacitor structure in the printed circuit board in FIG. 2. FIG. 4 illustrates a diagram of a sectional view of a capacitor structure in a printed circuit board according to another embodiment of the present invention, in FIG. 4. The deposition layer 20′ is manufactured from a core substrate process.

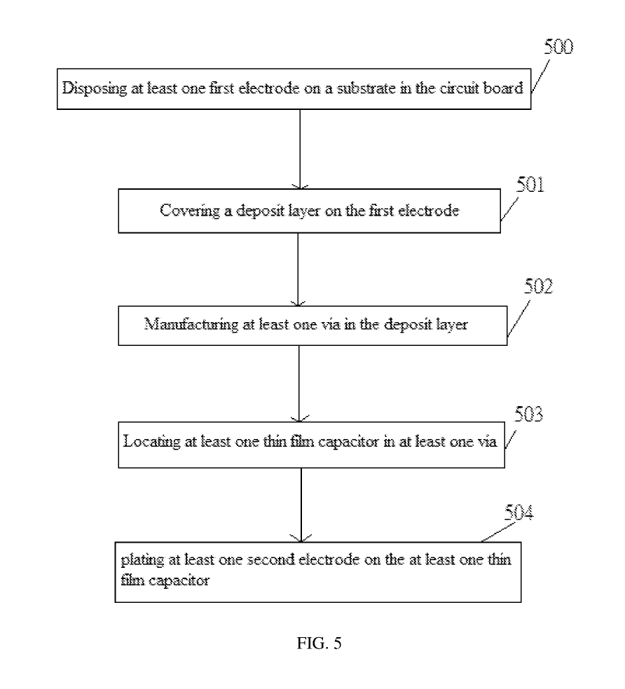

An embodiment of the present invention discloses a manufacturing method of a circuit board having a via capacitor structure, please refer to FIG. 5. FIG. 5 illustrates a diagram of a manufacture flowchart of a capacitor structure in a printed circuit board according to an embodiment of the present invention, including the following steps:

S500: disposing at least one first electrode on a substrate in the circuit board;

S501: covering a deposition layer on the first electrode;

S502: manufacturing at least one via in the deposition layer;

S503: locating at least one thin film capacitor in at least one via; and

S504: plating at least one second electrode on the at least one thin film capacitor.

In step S503, each of the at least one thin film capacitor is disposed in each of the at least one via, each of the at least one thin film capacitor has a body, a second terminal, and a first terminal, wherein the second terminal and the first terminal are located on two opposite sides of the body, each of the at least one first electrodes is electrically connected to the first terminal of each of the at least one thin film capacitors. In step S504, each of the at least one second electrodes electrically connected to the second terminal of each of the at least one thin film capacitors. At least one thin film capacitor formed in the at least one via is a capacitor connected in parallel, in this way, different numbers of the vias are adjusted to determine a total capacitance of the capacitor formed. The material of the thin film capacitor could be a material with a medium, or high permittivity, and the chemical composition contains a metallic and non-metallic elements, and consists of two or more elements, such as BaTiO₃, TiO₂ etc., if the dielectric material selected has electrical leakage, then isolation layer such as Ti, TiN, etc., can be added between the electrode and dielectric material. The first electrode is a metal material, and may be an alloy, such as Cu, Au, NiCo, etc.

The disposing and welding method of the capacitor structure used in the present invention is different from that of a physical capacitor. The present invention can change the deposit thin film capacitor process of permittivity according to the requirement of the capacitance, and control the process quality more easily, adjusting a thickness of the via through adjusting the aperture and selecting the permittivity of the capacitor material, and apply the second and first electrodes connected in parallel in the via to form thin film capacitors connected in parallel. Through controlling the number of the thin film capacitors/vias to achieve the predetermined capacitance, and the capacitor trace can be directly performed in the circuit layout, without increasing the element volume. Because the signal transmission route is shortened, it is helpful for the power source allocation, and the effect of the current fluctuation in the transmission route is decreased, the power integration is thus improved.

In summary, although the present invention has been described in preferred embodiments above, the preferred embodiments described above are not intended to limit the invention. Persons skilled in the art, without departing from the spirit and scope of the invention otherwise, may be used for a variety modifications and variations, so the scope of the invention as defined by the claims prevails.

What is claimed is:

1. A circuit board having a via capacitor structure, comprising:
a base;
a deposition layer disposed on the base, having at least one via in the deposition layer;
at least one thin film capacitor, each of the at least one thin film capacitors disposed in each of the at least one vias, each of the at least one thin film capacitors having a body, a second terminal, and a first terminal, wherein the second terminal and the first terminal are located on two opposite sides of the body;
at least one first electrode, each of the at least one first electrodes electrically connected to the first terminal of each of the at least one thin film capacitors; and
at least one second electrode, each of the at least one second electrodes electrically connected to the second terminal of each of the at least one thin film capacitors;
wherein a signal is sent from the first electrode to the second electrode via the body of the at least one thin film capacitor in order to allow a collinear route of the first electrode, the body, and the second electrode to transmit the signal.

2. The circuit board having a via capacitor structure of claim 1, wherein the circuit board is manufactured from a core substrate process.

3. The circuit board having a via capacitor structure of claim 1, wherein the circuit board is manufactured from a build-up process.

4. The circuit board having a via capacitor structure of claim 1, wherein the second electrode is a power source electrode, and the first electrode is a ground electrode.

5. The circuit board having a via capacitor structure of claim 1, wherein a surface of the first terminal completely and electrically contacts a surface of each of the at least one first electrodes, and a surface of the second terminal completely and electrically contacts a surface of each of the at least one second electrodes.

6. The circuit board having a via capacitor structure of claim 1, wherein the first electrode, the body, and the second electrode form an alignment state along the collinear route.

7. The circuit board having a via capacitor structure of claim 1, wherein a method of forming the at least one via is selected from a group consisting of machine drill, laser, plasma, and lithography processes.

8. The circuit board having a via capacitor structure of claim 1, wherein a method of forming the at least one thin film capacitor is selected from a group consisting of sputtering, evaporation, atom layer deposit, printing and dispensing.

9. A manufacturing method of a circuit board having a via capacitor structure, comprising the following steps:
disposing at least one first electrode on a substrate of the circuit board;
covering a deposition layer on the first electrode;
manufacturing at least one via in the deposition layer;
disposing at least one thin film capacitor in at least one via, each of the at least one thin film capacitors disposed in each of the at least one vias, each of the at least one thin film capacitors having a body, a second terminal, and a first terminal, wherein the second terminal and the first terminal are located on two opposite sides of the body, each of the at least one first electrodes is electrically connected to the first terminal of each of the at least one thin film capacitor; and
coating at least one second electrode on the at least one thin film capacitor, each of the at least one second electrodes electrically connected to the second terminal of each of the at least one thin film capacitors.

10. The manufacturing method of claim 9, wherein the circuit board is manufactured from a core substrate process.

11. The manufacturing method of claim 9, wherein the circuit board is manufactured from a build-up process.

12. The manufacturing method of claim 9, wherein a method of forming the at least one via is selected from a group consisting of machine drill, laser, plasma, and lithography processes.

13. The manufacturing method of claim 9, wherein a method of forming the at least one thin film capacitor is selected from a group consisting of sputtering, evaporation or atom layer deposit, printing and dispensing.
